(19) United States
(12) Patent Application Publication
(10) Pub. No.: US 2012/0249177 A1
(43) Pub. Date: Oct. 4, 2012

(54) HANDLER TRAY, SYSTEM AND METHOD OF TESTING AN OBJECT INCLUDING THE SAME

(75) Inventors: Gui-Heum CHOI, Asan-si (KR); Doo-Seob KIM, Cheonan-si (KR); Jong-An LEE, Cheonan-si (KR); Young-Gil LEE, Cheonan-si (KR); Seoung-Su HA, Cheonan-si (KR); Seung-Hee LEE, Cheonan-si (KR)

(73) Assignee: Samsung Electronics Co., Ltd, Suwon-si (KR)

(21) Appl. No.: 13/403,432

(22) Filed: Feb. 23, 2012

(30) Foreign Application Priority Data
Mar. 30, 2011 (KR) 10-2011-0028577

(51) Int. Cl. G01R 31/26; G01R 31/00

(52) U.S. Cl. 324/756.02

(57) ABSTRACT

A handler tray may include a tray body and a socket. The tray body may be configured to receive an object. The tray body with the object may be transferred to a test board. The tray body may be selectively interposed between the object and the test board to supply a test current from the test board to external terminals of the object. The socket may be formed on the tray body. The socket may electrically make contact with the external terminals of the object. Thus, a pick-up robot and an insert may be unnecessary, so that a test system and method of testing the object may have an optimally available space.

### CROSS-REFERENCE TO RELATED APPLICATIONS

This application claims priority under 35 U.S.C. §119 from Korean Patent Application No. 2011-28577, filed on Mar. 30, 2011 in the Korean Intellectual Property Office (KIPO), the disclosure of which is incorporated herein by reference in its entirety.

### BACKGROUND

1. Field of the General Inventive Concept

Example embodiments relate to a handler tray, a system and method of testing an object including the same. More particularly, example embodiments relate to a handler tray used to test electrical characteristics of a semiconductor package, and a system and method of testing the electrical characteristics of the semiconductor package using the handler tray.

2. Description of the Related Art

Generally, a plurality of semiconductor fabrication processes may be performed on a semiconductor substrate to form a plurality of semiconductor chips. In order to mount the semiconductor chips on a printed circuit board (PCB), a packaging process may be performed on the semiconductor chips to form semiconductor packages. In order to test electrical characteristics of the semiconductor package, a test system to supply a test current to external terminals of the semiconductor package may be used.

The test system may include a transfer tray, an insert, a pick-up robot, a loading unit, a testing unit and an unloading unit. The transfer tray may be configured to receive the semiconductor packages. The insert may hold the semiconductor packages during testing of the semiconductor packages. The pick-up robot may transfer the semiconductor packages from the transfer tray to the insert. The loading unit may load the insert with the semiconductor packages into the testing unit. The testing unit may include a test board configured to electrically make contact with the external terminals of the semiconductor packages. The unloading unit may unload tested semiconductor packages from the testing unit.

The transfer tray may have partitions to firmly support each of the semiconductor packages. Thus, each of the partitions may have a size corresponding to each of the semiconductor packages. In contrast, because a test circuit may be formed on the test board, the test board may have a space, which may be configured to receive one semiconductor package, that is relatively larger than that of the transfer tray.

Therefore, in order to match the semiconductor package with the test board, the insert having a structure that may correspond to a structure of the test board may be required. Further, the pick-up robot to transfer the semiconductor packages in the transfer tray to the insert one-by-one may be required.

However, when the pick-up robot loads the semiconductor package into the insert, the semiconductor package may be frequently misaligned. Further, the insert and the pick-up robot to only hold the semiconductor packages may occupy large spaces in a test line.

Moreover, in order to test other kinds of semiconductor packages, it may be required to substitute the insert with a new insert having a structure corresponding to that of a new semiconductor package. As a result, in order to test the new semiconductor package, it may be required to stop the test system.

### SUMMARY

Example embodiments provide a handler tray capable of excluding uses of an insert and a pick-up robot.

Example embodiments also provide a system to continuously test various kinds of objects without stopping of an operation using the above-mentioned handler tray.

Additional features and utilities of the present general inventive concept will be set forth in part in the description which follows and, in part, will be obvious from the description, or may be learned by practice of the general inventive concept.

Embodiments of the present general inventive concept may be achieved by providing a handler tray. The handler tray may include a tray body and a socket. The tray body may be configured to receive at least one object. The tray body with the at least one object may be transferred to a test board. The tray body may be selectively interposed between the at least one object and the test board to supply a test current from the test board to external terminals of the at least one object. The socket may be formed on the tray body. The socket may electrically make contact with the external terminals of the at least one object.

In some example embodiments, the tray body may include a tray plate configured to receive the at least one object, and a test line formed in the tray plate to flow the test current therethrough.

In some example embodiments, the socket may include a socket plate formed on the tray plate, and socket pins formed on the socket plate to electrically make contact with the external terminals of the at least one object.

Embodiments of the present general inventive concept may also be achieved by providing a a system to test an object. The system may include a testing unit, a first transfer tray, a loading unit, a first handler tray and a reversing unit. The testing unit may test the object. The first transfer tray may be configured to receive the object. The loading unit may be arranged between the first transfer tray and the testing unit to transfer the object from the first transfer tray to the testing unit. The first handler tray may be placed on the object by the loading unit. The first handler with the object may be transferred to the testing unit. The first handler tray may supply a test current from the testing unit to external terminals of the object. The reversing unit may reverse the object and the first handler tray to orient the first handler tray in a downward direction.

In some example embodiments, the testing unit may include a test chamber, a test head arranged in the test chamber and received the test current, a test board arranged on the test head to electrically make contact with the first handler tray, and a pressurizing unit for downwardly pressurizing an upper surface of the object.

In some example embodiments, the loading unit may include a loading conveyor arranged between the first handler tray and the testing unit, a first robot to transfer the object from the first handler tray to the loading conveyor, and a second robot to transfer the first handler tray on the object placed on the loading conveyor.

In some example embodiments, the reversing unit may include a rotary driver to rotate the object and the first handler tray, and a lift to descend the loading conveyor during the rotary driver may rotate the object and the first handler tray.

In some example embodiments, the system may further include a second transfer tray and a second handler tray. The second transfer tray may be configured to receive a second object different from the object. The second handler tray may have a structure corresponding to that of the second object. The second handler tray may be placed on the second object by the loading unit. The second handler tray with the second object may be transferred to the testing unit. The second handler tray may supply the test current from the testing unit to external terminals of the second object.

In some example embodiments, the system may further include an unloading unit to unload a tested object from the testing unit. The unloading unit may include an unloading conveyor extending from the testing unit, and a third robot to pick an abnormal object among the objects on the unloading conveyor.

According to some example embodiments, the object in the handler tray may be reversed at an angle of about 180°, so that a pick-up robot and an insert may be unnecessary. Thus, the system may have an optimally available space. Further, a misalignment of the object caused by the pick-up robot may be prevented. Moreover, when a new object may be test, the used handler tray may be substituted with a new handler tray corresponding to the new object during the object may be tested. Therefore, stopping the system may not be required.

Embodiments of the present general inventive concept may also be achieved by providing a method of testing at least one object, the method including mounting a handler tray including a tray body and a socket with electrical pins onto a first loading stacker, mounting a transfer tray onto a second loading stacker and receiving at least one object into the transfer tray, transferring the transfer tray onto a loading conveyor and mounting the handler tray atop the transfer tray such that the electrical socket makes electrical contact with the at least one object, and loading the handler tray and the transfer tray into a testing unit to test electrical connectors of the at least one object.

The method may further include inverting the handler tray and transfer tray before loading into the testing unit, electrically connecting the tray body to a test board, and transferring electric current through the test board to the handler tray to test the electrical connections of the at least one object.

The method may further include unloading at least one normal test object to a first unloading stacker, unloading at least one abnormal test object to a second unloading stacker; and unloading the handler tray to a third unloading stacker.

The method may further include pressurizing an upper surface of the at least one object such that the electrical connectors of the at least one object accurately make contact with the electrical pins of the socket.

The object may include at least one semiconductor package.

### BRIEF DESCRIPTION OF THE DRAWINGS

Example embodiments will be more clearly understood from the following detailed description taken in conjunction with the accompanying drawings. FIGS. 1 to 9 represent non-limiting, example embodiments as described herein.

These and/or other features and utilities of the present general inventive concept will become apparent and more readily appreciated from the following description of the embodiments, taken in conjunction with the accompanying drawings of which:

FIG. 1 is a cross-sectional view illustrating a handler tray in accordance with some example embodiments of the present general inventive concept;

FIG. 2 is a block diagram illustrating a test system including the handler tray in FIG. 1 of the present general inventive concept; and

FIGS. 3 to 9 are cross-sectional views illustrating operations of the test system in FIG. 2.

### DETAILED DESCRIPTION OF THE EMBODIMENTS

Various example embodiments will be described more fully hereinafter with reference to the accompanying drawings, in which some example embodiments are shown. The present general inventive concept may, however, be embodied in many different forms and should not be construed as limited to the example embodiments set forth herein. Rather, these example embodiments are provided so that this disclosure will be thorough and complete, and will fully convey the scope of the present general inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present general inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present general inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present general inventive concept.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

### Handler Tray

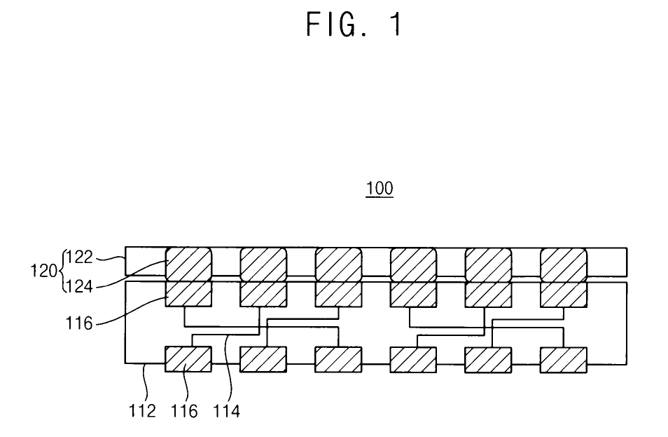

FIG. 1 is a cross-sectional view illustrating a handler tray in accordance with some example embodiments.

Referring to FIG. 1, a handler tray 100 of this example embodiment may include a tray body 110 and a socket 120. The handler tray 100 may be transferred to a testing unit with an object. In some example embodiments, the object may include a semiconductor package.

The tray body 110 may include a tray plate 112, a plurality of test lines 114 and a plurality of tray pins 116. In some example embodiments, the tray plate 112 may have a structure corresponding to that of a transfer tray (not illustrated) in which the semiconductor packages may be stacked. The tray plate 112 may include an insulating material.

The test lines 114 may be formed in or on the tray plate 112 between the tray pins 116. A test current to test electrical characteristics of the semiconductor packages may flow through the tray pins 116 and test lines 114. Thus, when the tray body 110 may be arranged on a test board (not illustrated) to supply the test current, the test lines 114 may be electrically connected to the test board via the tray pins.

The socket 120 may be formed on the tray body 110. The socket 120 may include a socket plate 122 and socket pins 124. The socket plate 122 may be arranged on an upper surface of the tray plate 112. In some example embodiments, the socket plate 122 may include an insulating material to provide an insulating layer between the socket 120 and the tray body 110. However, the present general inventive concept is not limited thereto. An air gap insulating layer may be formed between the socket 120 and the tray body 110, or the socket 120 and tray body 110 may be formed flush with one another, with no insulating layer therebetween.

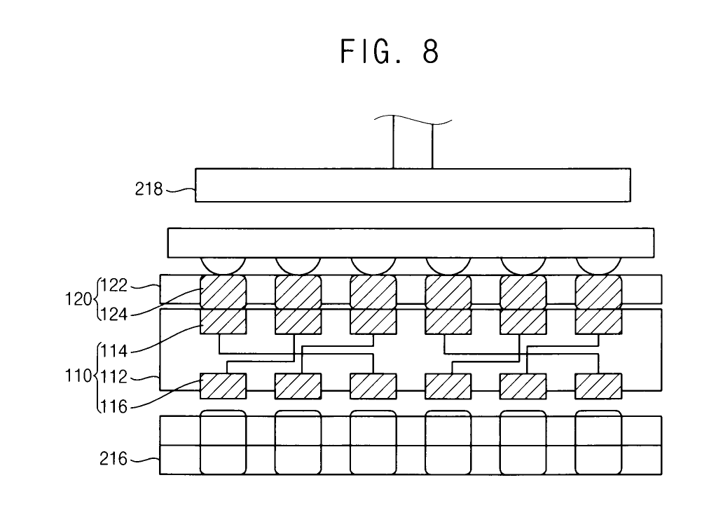

The socket pins 124 may be arranged to pass through the socket plate 122 or on an upper surface of the socket plate 122. The socket pins 124 may be electrically connected to the test lines 114. Therefore, the test current may flow to the socket pins 124 through the test lines 114 and tray pins 116. External terminals 305 of the semiconductor packages 300 (illustrated in FIG. 8) may electrically make contact with the socket pins 124.

According to this example embodiment, the handler tray 100 may have a function to allow the test current to flow therethrough as well as a function to hold and transfer the semiconductor packages. Thus, it may not be required to use an insert to merely hold the semiconductor packages. Further, it may not be required to use a pick-up robot to transfer the semiconductor packages from the transfer tray to the insert.

### System to Test an Object

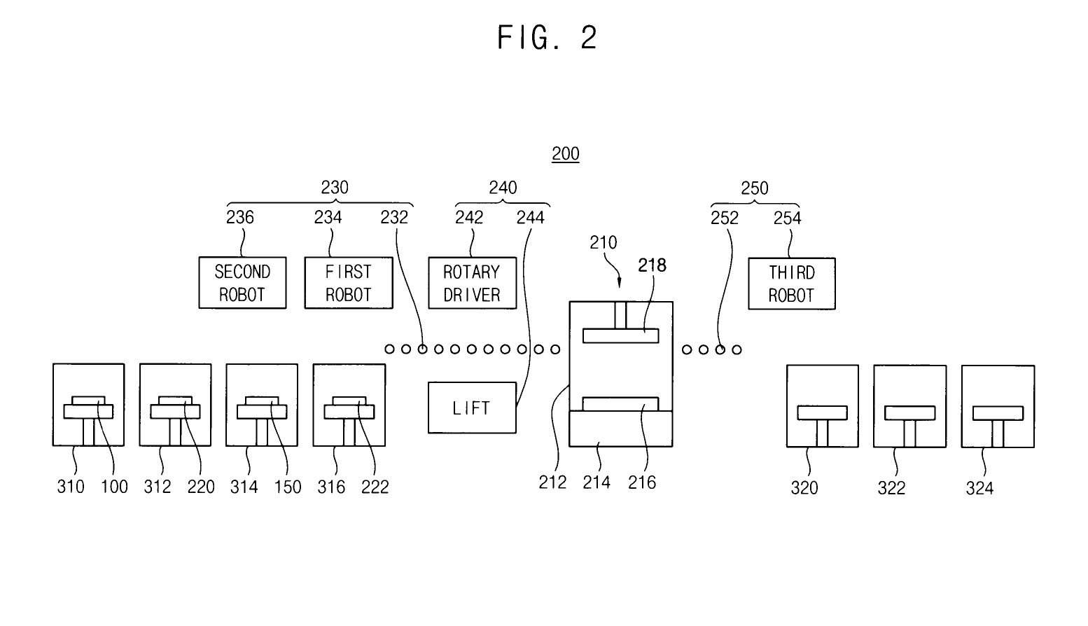

FIG. 2 is a block diagram illustrating a test system including the handler tray in FIG. 1.

Referring to FIG. 2, a test system 200 of this example embodiment may include a first handler tray 100, a first transfer tray 220, a loading unit 230, a reversing unit 240, a testing unit 210 and an unloading unit 250. In some example embodiments, the first handler tray 100, the first transfer tray 220, the loading unit 230, the reversing unit 240, the testing unit 210 and the unloading unit 250 may be sequentially arranged left to right, but the example embodiments are not limited thereto. The various units may be arranged right to left, or may be arranged in a non-linear fashion depending on the space allowed in a fabrication and test facility.

In some example embodiments, the first handler tray 100 may include elements substantially the same as those of the handler tray 100 in FIG. 1. Thus, the same reference numerals may refer to the same elements and any further illustrations with respect to the same elements may be omitted herein for brevity. The first handler tray 100 may be placed in a first loading stocker 310. The socket 120 of the first handler tray 100 may be arranged oriented toward a downward direction, thus inverting the elements illustrated in FIG. 1.

The first transfer tray 220 may be placed in a second loading stocker 312. A plurality of first semiconductor packages 300 (illustrated in FIG. 8) may be received in the first transfer tray 220.

The loading unit 230 may be arranged between the first handler tray 100 and the first transfer tray 220, and the testing unit 210. The loading unit 230 may include a loading conveyor 232, a first robot 234 and a second robot 236.

The loading conveyor 232 may be connected between the first transfer tray 220 and the testing unit 210. The first robot 234 may pick the first transfer tray 220 up from second loading stocker 312 and put the first transfer tray 220 on the loading conveyor 232. The second robot 236 may pick the first handler tray 100 up from the first loading stocker 310 and put the first handler tray 100 on the first semiconductor package received in the first transfer tray 220 placed on the loading conveyor 232. In some example embodiments, the socket 120 in the first loading stocker 310 may be oriented toward the downward direction. Thus, when the second robot 236 may put the first handler tray 100 on the first semiconductor package, the socket 120 may make contact with the external terminals of the first semiconductor package.

The reversing unit 240 may be arranged adjacent to the loading conveyor 232. The reversing unit 240 may include a rotary driver 242 and a lift 244.

The rotary driver 242 may rotate the first handler tray 100 and the first transfer tray 220 at an angle of about 180°. Thus, the first semiconductor package may be oriented toward an upward direction. In contrast, the first handler tray 100 may be oriented toward the downward direction. In some example embodiments, the rotary driver 242 may include a motor, a cylinder, etc.

In some example embodiments, because the rotary driver 242 may not rotate the first hander 100 and the first transfer tray 220 on the loading conveyor 232, the lift 244 may descend a part of the loading conveyor 232 with the rotary driver 244 holding the first hander tray 100 and the first transfer tray 220. After the rotary driver 242 may rotate the first handler tray 100 and the first transfer tray 220, the lift 244 may ascend the part of the loading conveyor 232. The loading conveyor 232 may transfer the first handler tray 100, the first transfer tray 220 and the first semiconductor packages received in the first transfer tray 220 to the testing unit 210.

The testing unit 210 may include a test chamber 212, a test head 214, a test board 216 and a pressurizing member 218.

The loading conveyor 232 may extend into the test chamber 212. In order to test the semiconductor packages under different temperatures, a temperature controller (not illustrated) may be arranged in the test chamber 212.

The test head 214 may be arranged in a bottom surface of the test chamber 212. The test current generated from a tester (not illustrated) may be supplied to the test head 214.

The test board 216 may be placed on the test head 214. The first handler tray 100 may be placed on the test board 216. In some example embodiments, the test board 216 may have test pads (not illustrated) corresponding to the external terminals of the first semiconductor packages received in the first transfer tray 220. The test pads may be electrically connected to the tray pins 116 and test lines 114 of the first handler tray 100.

The pressurizing member 218 may be located over the test board 216 in the test chamber 212. The pressurizing member 218 may pressurize an upper surface of the first semiconductor package on the test board 216. The external terminals of the pressurized first semiconductor package may accurately make contact with the socket pins 124 of the first handler tray 100. Therefore, electrical connections between the tray pins 116 and test lines 114 of the first handler tray 100 and the test pads of the test board 216 may be ensured.

The unloading unit 250 may unload tested first semiconductor packages by the testing unit 210. The unloading unit 250 may unload the first handler tray 100 and the first transfer tray 220 from the testing unit 210. The unloading unit 250 may include an unloading conveyor 252 and a third robot 254.

The unloading conveyor 252 may extend from the test chamber 212. The first handler tray 100 and the first transfer tray 220 may be unloaded from the test chamber 212 along the unloading conveyor 252.

The third robot 254 may transfer the first transfer tray 220 in which normal first semiconductor packages may be received to a second unloading stocker 322. In contrast, the third robot 254 may transfer the first transfer tray 220 in which abnormal first semiconductor packages may be received to a third unloading stocker 324. The second robot 236 may transfer the first handler tray 100 to the first unloading stocker 320.

Additionally, a second handler tray 150 may be received in a third loading stocker 314. A second transfer tray 222 may be received in a fourth loading stocker 316. Second semiconductor packages different from the first semiconductor packages may be received in the second transfer tray 222. The second handler tray 150 may have a structure corresponding to that of the second semiconductor package.

In some example embodiments, in order to sequentially test the first semiconductor packages and the second semiconductor packages, the first robot 234 may prepare to transfer the second transfer tray 222 to the loading conveyor 232 during testing the first semiconductor packages. Further, the second robot 236 may prepare to transfer the second handler tray 150 to the second transfer tray 222. That is, these preparations may be performed during testing the first semiconductor packages. Thus, it may be required to prepare a new handler tray corresponding to a new object without stopping of the test system 200.

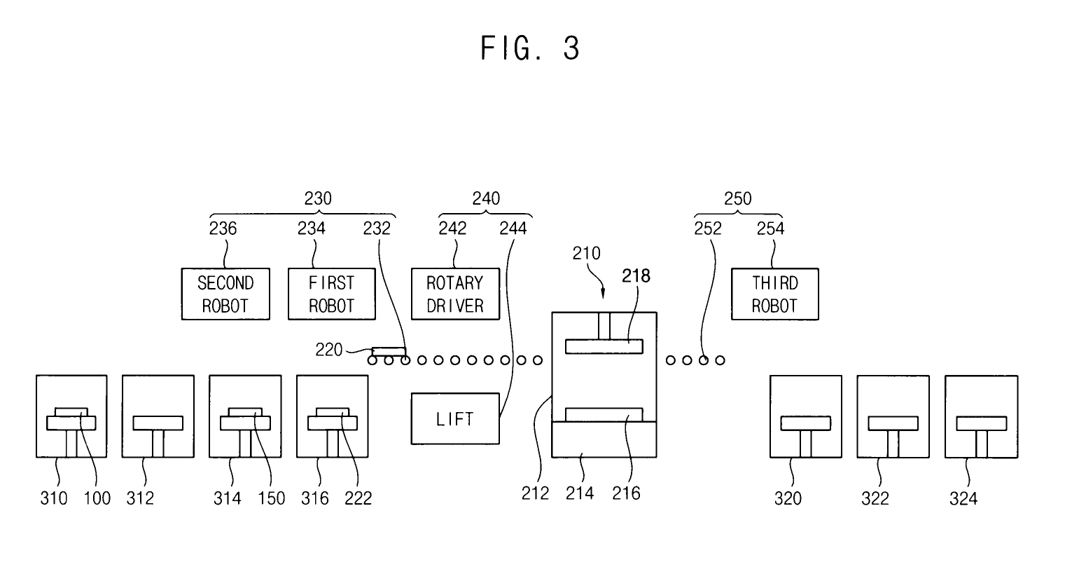

FIGS. 3 to 9 are cross-sectional views illustrating operations of the test system in FIG. 2.

Referring to FIG. 3, the first robot 234 may transfer the first transfer tray 220 in which the first semiconductor packages may be received from the second loading stocker 312 to the loading conveyor 232.

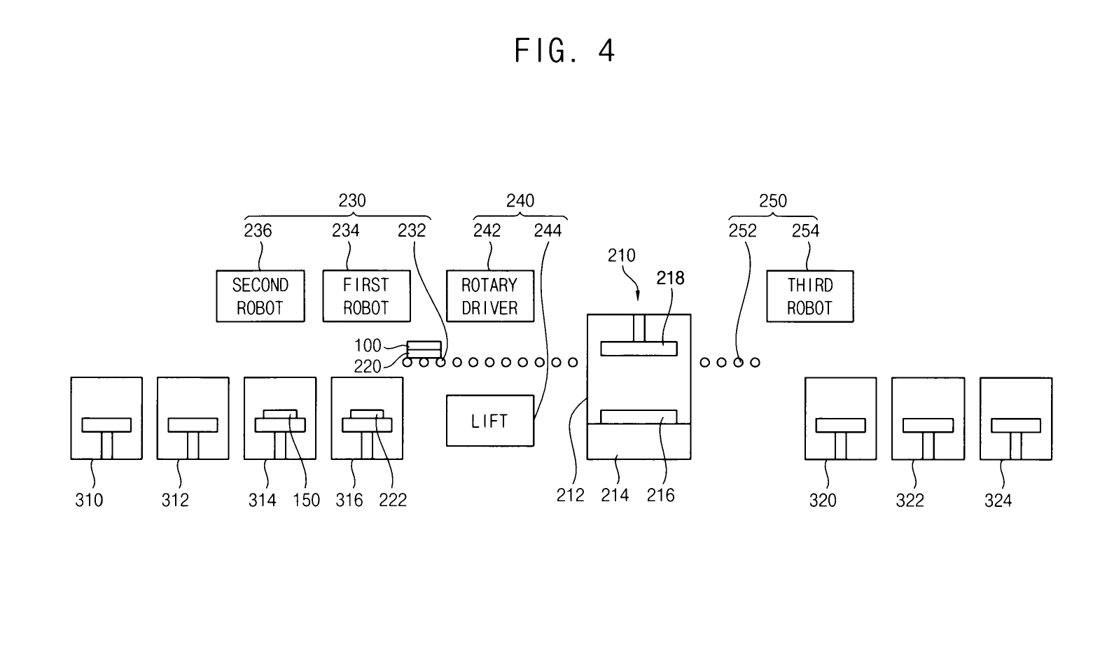

Referring to FIG. 4, the second robot 236 may transfer the first handler tray 100 from the first loading stocker 310 to the upper surface of the first transfer tray 220. The first handler tray 100 may be stacked on the first semiconductor packages. Because of a downward direction arrangement, described previously, the socket 120 of the first handler tray 100 may make contact with the first semiconductor packages.

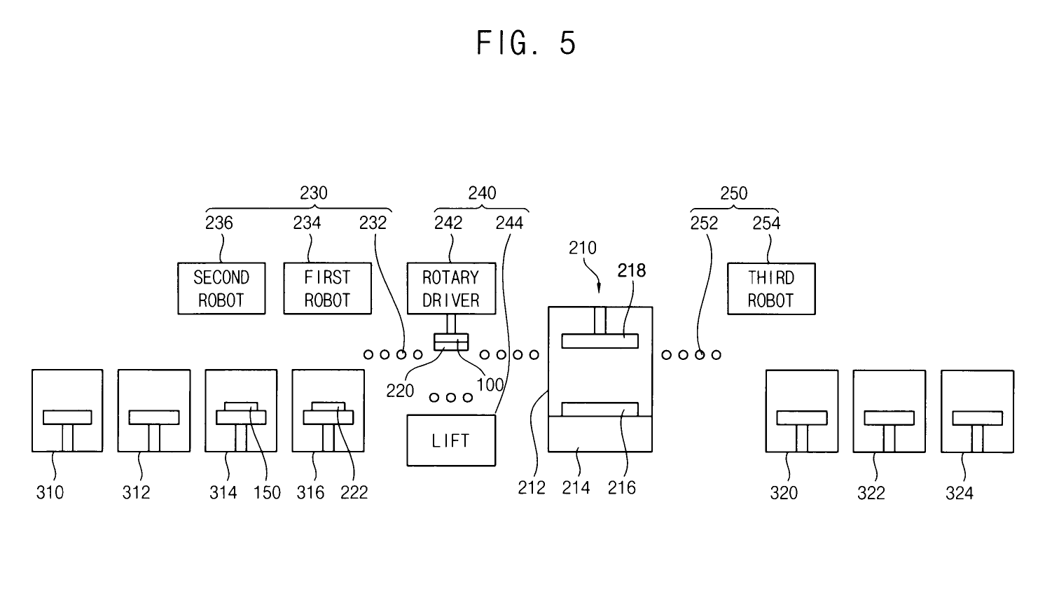

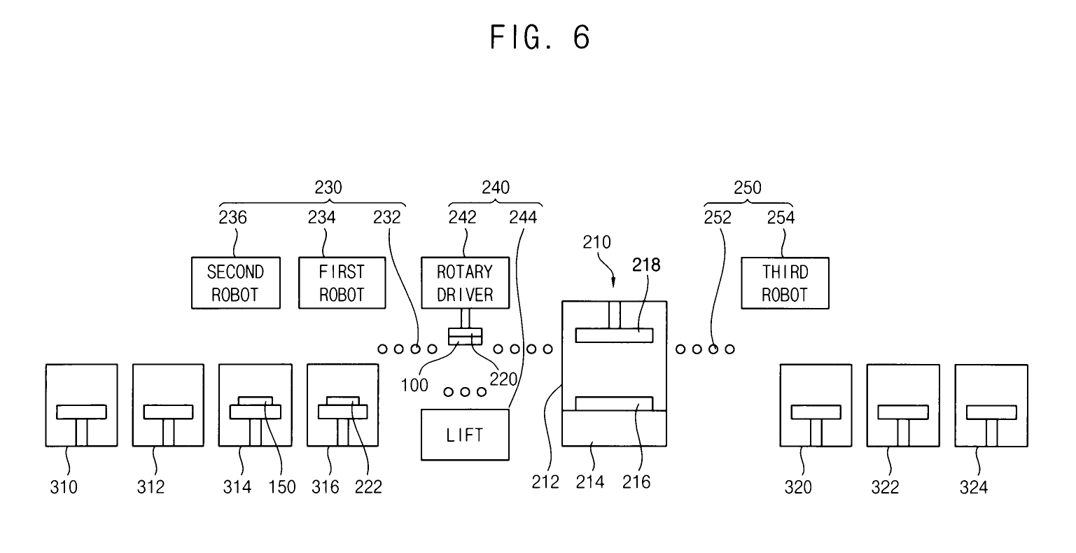

Referring to FIGS. 5 and 6, the first handler tray 100 and the first transfer tray 220 moved on the loading conveyor 232 may be stopped at a position where the reversing unit 240 may be located.

The rotary driver 242 may firmly hold the first handler tray 100 and the first transfer tray 220. The lift 244 may descend the part of the loading conveyor 232. The rotary driver 242 may inversely rotate the first handler tray 100 and the first transfer tray 220 at an angle of about 180°. Thus, the first semiconductor packages received in the first transfer tray 220 may be inverted and placed on the first handler tray 100.

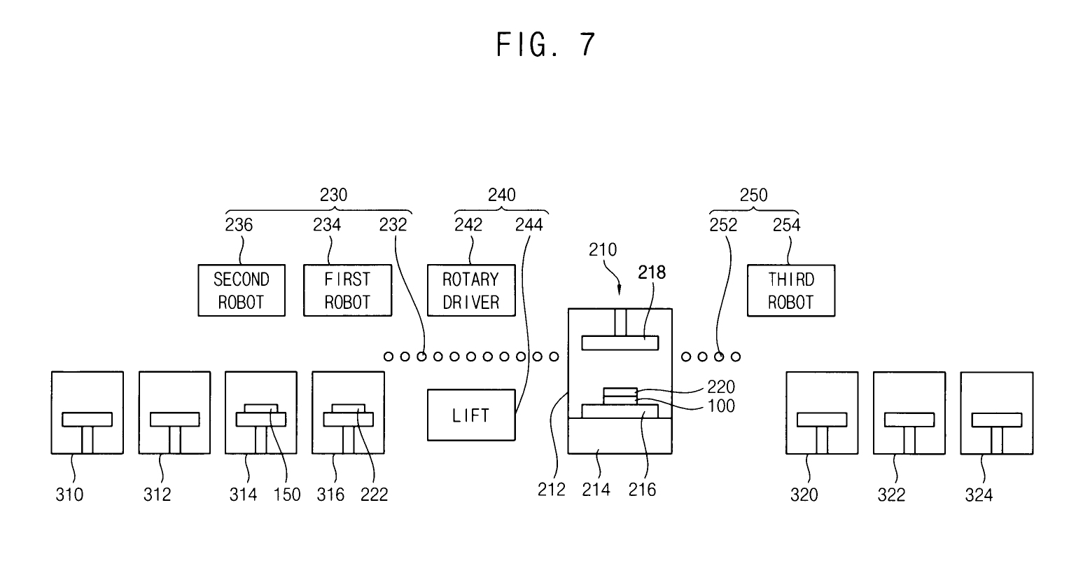

Referring to FIGS. 6 and 7, the lift 244 may ascend the part of the loading conveyor 232 to put the first handler tray 100 on the part of the loading conveyor 232.

Referring to FIG. 7, the loading conveyor 232 may load the first handler tray 100 and the first transfer tray 220 into the testing unit 210. That is, the first handler tray 100 and the first transfer tray 220 may be loaded into the test chamber 212.

The pressurizing member 218 may pressurize the upper surfaces of the first semiconductor packages received in the first transfer tray 220.

As illustrated FIG. 8, the external terminals 305 of the first semiconductor packages 300 may make contact with the socket pins 124 of the first handler tray 100. Further, the tray pins 16 and test lines 114 of the first handler tray 100 may electrically make contact with the test board 216.

The test current generated from the tester may be supplied to the test board 216 through the test head 214. The test current may be applied to the external terminals of the first semiconductor packages through the tray pins 116 and test lines 114 and the socket pins 124 to test electrical characteristics of the first semiconductor packages.

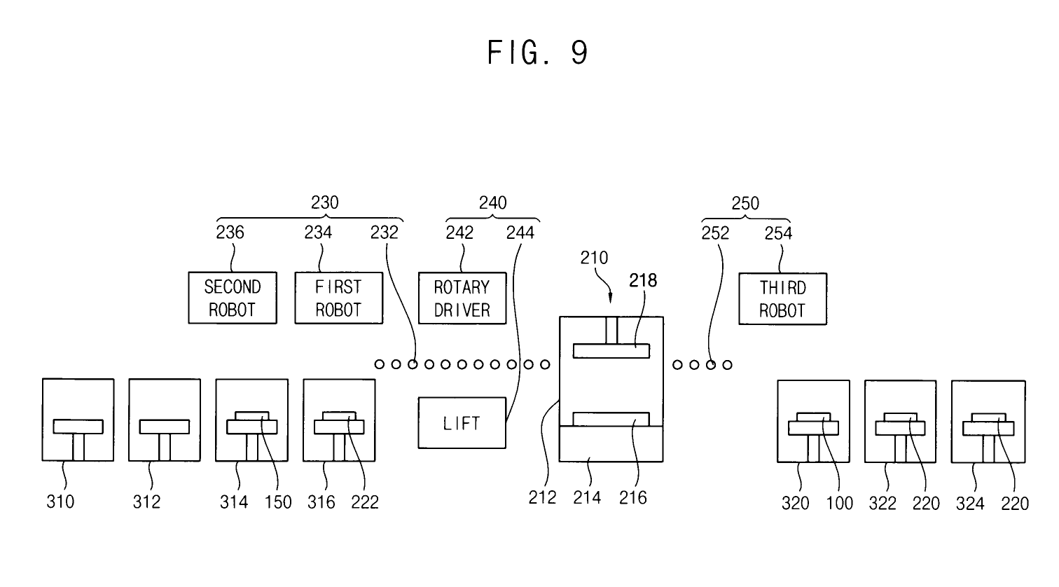

Referring to FIG. 9, the tested first semiconductor packages may be unloaded from the testing unit 210 along the unloading conveyor 252. The third robot 254 may transfer the normal first semiconductor packages to the second unloading stocker 322. In contrast, the third robot 324 may transfer the abnormal first semiconductor packages to the third unloading stocker 324.

The second robot 235 may transfer the first handler tray 100 to the first unloading stocker 320 to complete the test of the first semiconductor packages.

Additionally, in order to continuously test the second semiconductor packages after the first semiconductor packages, the first robot 234 may prepare to transfer the second transfer tray 222 to the loading conveyor 232 during testing the first semiconductor packages in the testing unit 210. Further, the second robot 236 may prepare to transfer the second handler tray 150 to the second transfer tray 222. That is, these preparations may be performed during testing the first semiconductor packages in the testing unit 210. Thus, the elements of the system may be required to prepare a new handler tray corresponding to a new object without stopping of the test system 200.

According to these example embodiments, objects in the handler tray may be reversed at an angle of about 180°, so that a pick-up robot and an insert may be unnecessary. Thus, the system may have an optimally available space. Further, a misalignment of the object caused by the pick-up robot may be prevented. Moreover, when a new object may be test, the used handler tray may be substituted with a new handler tray corresponding to the new object during the object may be tested. Therefore, stopping the system may not be required.

Though not illustrated, the operations of the various elements described above may be controlled by a control unit that includes a microprocessor. Programs to operate the system as described herein may be stored in a memory unit that includes ROM and RAM memory. The order of operations described above may be pre-set into ROM to be executed by the control unit, or may be input to the system by a user via direct access using a user interface panel, or by loading an algorithm into memory.

The foregoing is illustrative of example embodiments and is not to be construed as limiting thereof. Although a few example embodiments have been described, those skilled in the art will readily appreciate that many modifications are possible in the example embodiments without materially departing from the novel features and utilities of the present general inventive concept. Accordingly, all such modifications are intended to be included within the scope of the present general inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A handler tray comprising:
a tray body selectively interposed between at least one object and a test board to supply a test current from the test board to external terminals of the at least one object, the tray body transferred to the test board with the at least one object; and
a socket formed on the tray body to electrically make contact with the external terminals of the at least one object.

2. The handler tray of claim 1, wherein the tray body comprises:
a tray plate configured to receive the at least one object; and
a test line formed in the tray plate, the test current flowing through the test line.

3. The handler tray of claim 1, wherein the socket comprises:
a socket plate formed on the tray body; and
socket pins formed on the socket plate to make contact with the external terminals of the at least one object.

4. The handler tray of claim 1, wherein the at least one object comprises at least one semiconductor package.

5. A system to test an object, the system comprising:
a testing unit to test the object;
a first transfer tray configured to receive the object;
a loading unit arranged between the first transfer tray and the testing unit to load the object from the first transfer tray into the testing unit;
a first handler tray placed on the object by the loading unit and transferred to the testing unit, the first handler tray to supply a test current from the testing unit to external terminals of the object; and
a reversing unit to reverse the object and the first handler tray to orient the first handler tray in a downward direction.

6. The system of claim 5, wherein the testing unit comprises:
a test chamber;
a test head arranged in the test chamber to receive the test current;
a test board arranged on the test head to electrically make contact with the first handler tray; and
a pressurizing member arranged in the test chamber to downwardly pressurize an upper surface of the object.

7. The system of claim 5, wherein the loading unit comprises:
a loading conveyor arranged between the first transfer tray and the testing unit;
a first robot to transfer the object from the first transfer tray to the loading conveyor; and
a second robot to transfer the first handler tray to an upper surface of the object placed on the loading conveyor.

8. The system of claim 5, wherein the reversing unit comprises:
a rotary driver to rotate the object and the first handler tray; and
a lift to descend a part of the loading conveyor during the rotary driver rotates the object and the first handler tray.

9. The system of claim 5, wherein the first handler tray comprises:
a tray body configured to receive the object and to supply the test current to external terminals of the object; and
a socket formed on the tray boy to electrically make contact with the external terminals of the object.

10. The system of claim 9, wherein the tray body comprises:
a tray plate configured to receive the object; and
a test line formed in the tray plate, the test current flowing through the test line.

11. The system of claim 9, wherein the socket comprises:
a socket plate formed on the tray body; and
socket pins formed on the socket plate to make contact with the external terminals of the object.

12. The system of claim 5, further comprising:
a second transfer tray configured to receive a second object different from the object; and
a second handler tray having a structure to correspond to that of the second object, the second handler tray placed on the second object by the loading unit and transferred to the testing unit, the second handler tray to supply the test current to external terminals of the second object.

13. The system of claim 5, further comprising an unloading unit to unload the object tested by the testing unit.

14. The system of claim 13, wherein the unloading unit comprises;
an unloading conveyor extending from the testing unit; and
a third robot to pick an abnormal object up among the object on the unloading conveyor.

15. The system of claim 5, wherein the object comprises a semiconductor package.

16. A method of testing at least one object, the method comprising:
mounting a handler tray including a tray body and a socket with electrical pins onto a first loading stacker;
mounting a transfer tray onto a second loading stacker and receiving at least one object into the transfer tray;
transferring the transfer tray onto a loading conveyor and mounting the handler tray atop the transfer tray such that the electrical socket makes electrical contact with the at least one object; and
loading the handler tray and the transfer tray into a testing unit to test electrical connectors of the at least one object.

17. The method of claim 16, further comprising:
inverting the handler tray and transfer tray before loading into the testing unit;
electrically connecting the tray body to a test board; and
transferring electric current through the test board to the handler tray to test the electrical connections of the at least one object.

18. The method of claim 16, further comprising:
unloading at least one normal test object to a first unloading stacker;
unloading at least one abnormal test object to a second unloading stacker; and
unloading the handler tray to a third unloading stacker.

19. The method of claim 16, further comprising:
pressurizing an upper surface of the at least one object such that the electrical connectors of the at least one object accurately make contact with the electrical pins of the socket.

20. The method of claim 16, wherein the object comprises at least one semiconductor package.
